(19) United States
(12) Patent Application Publication
(10) Pub. No.: US 2012/0115313 A1
(43) Pub. Date: May 10, 2012

(54) SEMICONDUCTOR DEVICE MANUFACTURING APPARATUS AND METHOD

(75) Inventor: Hiroshi SATO, Nirasaki-shi (JP)

(73) Assignee: TOKYO ELECTRON LIMITED, Minato-Ku (JP)

(21) Appl. No.: 13/354,624

(22) Filed: Jan. 20, 2012

Related U.S. Application Data
(62) Division of application No. 12/475,060, filed on May 29, 2009.
Application No. 12/475,060 is a continuation of application No. PCT/JP07/72801, filed on Nov. 27, 2007.

(30) Foreign Application Priority Data
Nov. 30, 2006 (JP) 2006-322995

(51) Int. Cl. H01L 21/208

(52) U.S. Cl. 438/478; 257/E21.114

(57) ABSTRACT

A sealing member is lifted to cause its edge to be in contact with a contact surface of a support member. In the state where a precision ejection nozzle is isolated, a gas exhaust unit is operated to exhaust the inside of a chamber to reduce the pressure in the chamber to a predetermined level. Then, a purge gas is introduced into the chamber from a purge gas supply source through a gas introduction section to replace the atmosphere in the chamber with the purge gas, and the pressure in the chamber is returned to the atmospheric pressure. After that, the sealing member is lowered to release the isolation of the precision ejection nozzle. Then, liquid droplets of a liquid device material are ejected toward the surface of a substrate while a carriage is reciprocated in the X direction.

### CROSS REFERENCE TO RELATED APPLICATION

The present divisional application claims the benefit of priority under 35 U.S.C. 120 to application Ser. No. 12/475,060, filed May 29, 2009 which is a Continuation Application of PCT International Application No. PCT/JP2007/072801 filed on Nov. 27, 2007, which designated the United States, and claims the benefit of priority under 35 U.S.C. 119 from Japanese Application No. 2006-322995, filed on Nov. 30, 2006. Application Ser. No. 12/475,060 is hereby incorporated by reference in its entirety.

### FIELD OF THE INVENTION

The present invention relates to a semiconductor device manufacturing apparatus and manufacturing method.

### BACKGROUND OF THE INVENTION

In a process for manufacturing various semiconductor devices including transistors, wiring and the like on a silicon wafer, an FPD substrate or the like, basic processes such as patterning, etching, ashing, cleaning and the like are repeatedly performed, wherein the patterning is performed by a photolithography technique including each of processes such as resist coating, exposure and development. Currently, in order to obtain high processing precision, a high vacuum technique or a plasma technique is used in manufacturing semiconductor devices.

A semiconductor device manufacturing apparatus tends to be scaled up in order to deal with scaling up of a substrate or material change caused by technology node advance, and it is necessary to repeatedly improve the apparatus configuration or the processes. Further, due to a demand for reduction of environmental loads through cost reduction and energy saving, it is important to select a semiconductor device manufacturing apparatus capable of suppressing power consumption required for manufacturing the semiconductor devices.

Therefore, as for a new semiconductor device manufacturing apparatus, there has been proposed a technique for manufacturing semiconductor devices by ejecting a semiconductor device material in the form of fine liquid droplets toward a surface of an object to be processed, e.g., a substrate or the like (hereinafter, referred to as a “liquid droplet ejection method”) (e.g., Japanese Patent Laid-open Publications No. 2003-266669 (Patent Document 1) and No. 2003-311197 (Patent Document 2)).

The techniques provided to manufacture semiconductor devices by using the liquid droplet ejection method described in Patent Documents 1 and 2 are advantageous in that manufacturing cost of semiconductor devices can be greatly reduced by removing processes such as photolithography, etching and the like.

However, in the liquid droplet ejection method, all of semiconductor device materials need to be in liquid state in the form of solution, dispersion solution or the like, so that the following drawbacks can be generated. That is, liquid droplets ejected from a liquid droplet ejection nozzle are very fine and thus are subjected to deterioration such as change in solute concentration or oxidation of components due to the presence of moisture or oxygen in the atmosphere in a space where liquid droplets travel and further the presence of components volatilized from a substrate surface. This may affect the characteristics of the semiconductor devices.

In the liquid droplet ejection method, the semiconductor device materials in the form of liquid droplets are ejected from nozzle openings by abruptly varying an inner volume of a pressure chamber communicating with the fine nozzle openings by elongation and contraction of, e.g., piezoelectric ceramics or the like. For that reason, it is known that ejection performance is greatly affected by a state of a vapor-liquid interface, which is referred to as meniscuses, of a liquid material inside each of the nozzle openings. The meniscus is greatly affected by an ambient pressure, and the liquid material is ejected through each of the nozzle openings when the atmosphere outside the nozzle openings has a lower pressure than that in the pressure chamber. On the contrary, when the outside is under the higher pressure atmosphere, the liquid material retreats to the inner side of each nozzle opening. Therefore, in both cases, the normal ejection becomes impossible. As a consequence, the ejection space where the liquid droplets ejected from the nozzle arrive at the surface of the object to be processed, needs to be under the atmospheric condition. Accordingly, it is difficult to make the ejected liquid droplets subjected to a minimum affect by, e.g., changing the ejection space to a depressurized state.

### SUMMARY OF THE INVENTION

The object of the present invention is to provide a semiconductor device manufacturing apparatus and method which can effectively change the atmosphere in an ejection space so as to prevent, e.g., deterioration of liquid droplets ejected from a nozzle.

In accordance with a first aspect of the present invention, there is provided a semiconductor device manufacturing apparatus including: a mounting table for mounting thereon an object to be processed; a liquid droplet ejection unit having at least one liquid droplet ejection nozzle disposed to face the mounting table, for ejecting a semiconductor device material in the form of liquid droplets toward the object to be processed; and a nozzle isolation unit for isolating the liquid droplet ejection nozzle to maintain the liquid droplet ejection nozzle in an atmospheric pressure state.

In accordance with a second aspect of the present invention, a semiconductor device manufacturing apparatus including: a first vessel accommodating therein a mounting table for mounting thereon an object to be processed; a gas supply unit for supplying a purge gas into the first vessel; a gas exhaust unit for depressurizing the inside of the first vessel; a liquid droplet ejection unit having at least one liquid droplet ejection nozzle disposed to face the mounting table, for ejecting a semiconductor device material in the form of liquid droplets toward the object to be processed; and a second vessel for isolating the liquid droplet ejection nozzle to maintain the liquid droplet ejection nozzle in an atmospheric pressure state.

In the second aspect of the semiconductor device manufacturing apparatus, in a state where the inside of the first vessel is depressurized by the gas exhaust unit, the second vessel may accommodate therein the liquid droplet ejection unit to isolate the liquid droplet ejection nozzle, or in a state where the inside of the first vessel is depressurized by the gas exhaust unit, the second vessel may airtightly isolate the liquid droplet ejection nozzles by contacting with a nozzle forming surface where the liquid droplet ejection nozzle of the liquid droplet ejection unit is formed. Further, the second vessel may be accommodated in the first vessel.

The semiconductor device manufacturing apparatus described above may further include a moving unit for moving the liquid droplet ejection nozzle between a ejection position where the liquid droplets are ejected toward the object to be processed and a waiting position where the liquid droplets are not ejected, and the liquid droplet ejection nozzle is isolated by the second vessel in the waiting position.

In accordance with a third aspect of the present invention, a semiconductor device manufacturing apparatus including: a mounting table for mounting thereon an object to be processed; a liquid droplet ejection unit having at least one liquid droplet ejection nozzle disposed to face the mounting table, for ejecting a semiconductor device material in the form of liquid droplets toward the object to be processed; a vessel having an opening provided to be contacted with and separated from a surface of the object to be processed, for defining an ejection space where the liquid droplets ejected from the liquid droplet ejection nozzle travel, the liquid droplet ejection unit being accommodated in the vessel; a nozzle isolation unit for isolating the liquid droplet ejection nozzle from the ejection space; a gas supply unit for supplying a purge gas into the corresponding vessel in a state where the vessel is in contact with the surface of the object to be processed; a gas exhaust unit for depressurizing the inside of the vessel in a state where the vessel is in contact with the surface of the object to be processed; and a moving unit for moving the liquid droplet ejection unit relative to the mounting table.

In the first to third aspects of the semiconductor device manufacturing apparatus, the liquid droplet ejection unit may have a plurality of the liquid droplet ejection nozzles, and the liquid droplets include a conductive material, an insulating material and a semiconductor material which are separately ejected from the dedicated liquid droplet ejection nozzles.

In accordance with a fourth aspect of the present invention, a semiconductor device manufacturing method for producing a semiconductor device on a surface of an object to be processed by using a semiconductor device manufacturing apparatus including: a first vessel having a mounting table for mounting thereon the object to be processed; a gas supply unit for supplying a purge gas into the first vessel; a gas exhaust unit for depressurizing the inside of the first vessel; a liquid droplet ejection unit for ejecting a semiconductor device material in the form of liquid droplets from liquid droplet ejection nozzles disposed to face the mounting table toward the object to be processed; a moving unit for moving the liquid droplet ejection nozzles between an ejection position where the liquid droplets are ejected toward the object to be processed and a waiting position where the liquid droplets are not ejected; and a second vessel for isolating the liquid droplet ejection nozzles in the waiting position to maintain the liquid droplet ejection nozzles in an atmospheric pressure state.

The semiconductor device manufacturing method includes: loading the object to be processed into the first vessel to be mounted on the mounting table; depressurizing the inside of the first vessel in a state where the liquid droplet ejection nozzle is isolated by the second vessel in the waiting position; introducing the purge gas from the gas supply unit into the first vessel to replace the atmosphere in the first vessel with the purge gas and return a pressure in the first vessel to an atmospheric pressure; and releasing the isolation of the liquid droplet ejection nozzles, which is caused by the second vessel and moving the liquid droplet ejection nozzles to the ejection position to eject the liquid droplets toward the object to be processed.

In the fourth aspect of the semiconductor device manufacturing method, the method may further include heating the mounting table and the first vessel before the replacement of the atmosphere and sintering the formed device after the ejection of the liquid droplets from the liquid droplet ejection nozzle.

In accordance with a fifth aspect of the present invention, a semiconductor device manufacturing method for producing a semiconductor device on a surface of an object to be processed by using a semiconductor device manufacturing apparatus including: a mounting table for mounting thereon the object to be processed; a liquid droplet ejection unit for ejecting a semiconductor device material in the form of liquid droplets from a liquid droplet ejection nozzle disposed to face the mounting table toward the object to be processed; a vessel having an opening provided to be contacted with and separated from a surface of the object to be processed, for defining an ejection space where the liquid droplets ejected from the liquid droplet ejection nozzle travel, the liquid droplet ejection unit being accommodated in the vessel; a nozzle isolation unit for isolating the liquid droplet ejection nozzle from the ejection space; a gas supply unit for supplying a purge gas into the corresponding vessel in a state where the vessel is in contact with the surface of the object to be processed; a gas exhaust unit for depressurizing the inside of the vessel in a state where the vessel is in contact with the surface of the object to be processed; and a moving unit for moving the liquid droplet ejection unit relative to the mounting table.

The semiconductor device manufacturing method includes: moving the vessel relative to the object to be processed so as to face each other; causing the opening of the vessel to be in contact with the surface of the object to be processed; depressurizing the inside of the ejection space in a state where the liquid droplet ejection nozzle is isolated by the isolation unit inside the vessel; introducing the purge gas from the gas supply unit into the first vessel to replace the atmosphere in the first vessel with the purge gas and return a pressure in the first vessel to an atmospheric pressure; releasing the isolation of the liquid droplet ejection nozzle by the isolation unit; and ejecting the liquid droplets from the liquid droplet ejection nozzle toward the object to be processed.

In the fifth aspect of the semiconductor device manufacturing method, the method may further include heating the mounting table before the replacement of the atmosphere and sintering the formed device after the ejection of the liquid droplets from the liquid droplet ejection nozzle.

In accordance with the present invention, due to the presence of the isolation unit that isolates the liquid droplet ejection nozzle to maintain the atmospheric pressure, the atmosphere of the ejection space between the liquid droplet ejection nozzle and the object to be processed can be effectively and easily replaced. Therefore, it is possible to prevent deterioration of the semiconductor device material ejected in the form of liquid droplets from the liquid droplet ejection nozzle.

Further, by manufacturing semiconductor devices with the use of the liquid droplet ejection nozzle, it is possible to remove the photolithography process and realize simplification of the apparatus configuration, energy saving and cost reduction.

### BRIEF DESCRIPTION OF THE DRAWINGS

FIG. 1 is a perspective view showing a schematic inner configuration of a semiconductor device manufacturing apparatus in accordance with a first embodiment of the present invention.

FIG. 2 illustrates a schematic cross sectional view of the semiconductor device manufacturing apparatus in accordance with the first embodiment of the present invention.

FIG. 3 provides a principal part cross sectional view of an exemplary sealing configuration of a precision ejection nozzle.

FIG. 4 presents a principal part cross sectional view of another exemplary sealing configuration of the precision ejection nozzle.

FIG. 5 represents a principal part cross sectional view of still another exemplary sealing configuration of the precision ejection nozzle.

FIG. 6 offers a principal part cross sectional view of still another exemplary sealing configuration of the precision ejection nozzle.

FIG. 7 sets forth a flow chart showing an exemplary manufacturing procedure of a semiconductor device.

FIGS. 8A to 8E are process cross sectional views showing an exemplary manufacturing procedure of a capacitor.

FIG. 9 is a top view of a semiconductor device having a state shown in FIG. 8D.

FIG. 10 provides a partially cutout perspective view showing a schematic configuration of a semiconductor device in accordance with a second embodiment of the present invention.

FIG. 11 presents a schematic cross sectional view of the semiconductor device manufacturing apparatus in accordance with the second embodiment of the present invention.

FIG. 12 represents a principal part cross sectional view for explaining a partition plate.

FIG. 13 offers a flowchart describing another exemplary manufacturing procedure of a semiconductor device.

### DETAILED DESCRIPTION OF THE EMBODIMENT

The embodiments of the present invention will be described with reference to the accompanying drawings.

### First Embodiment

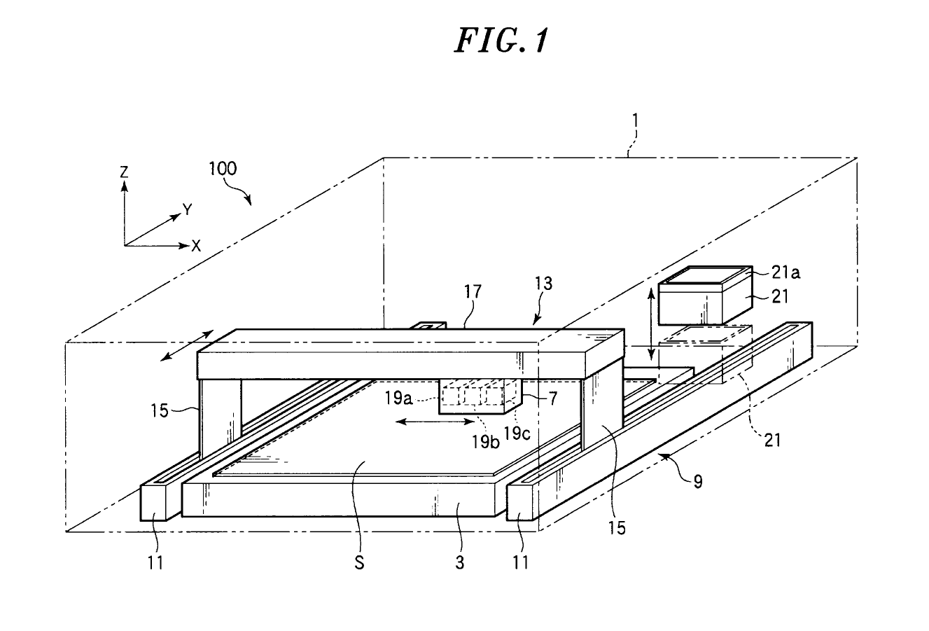

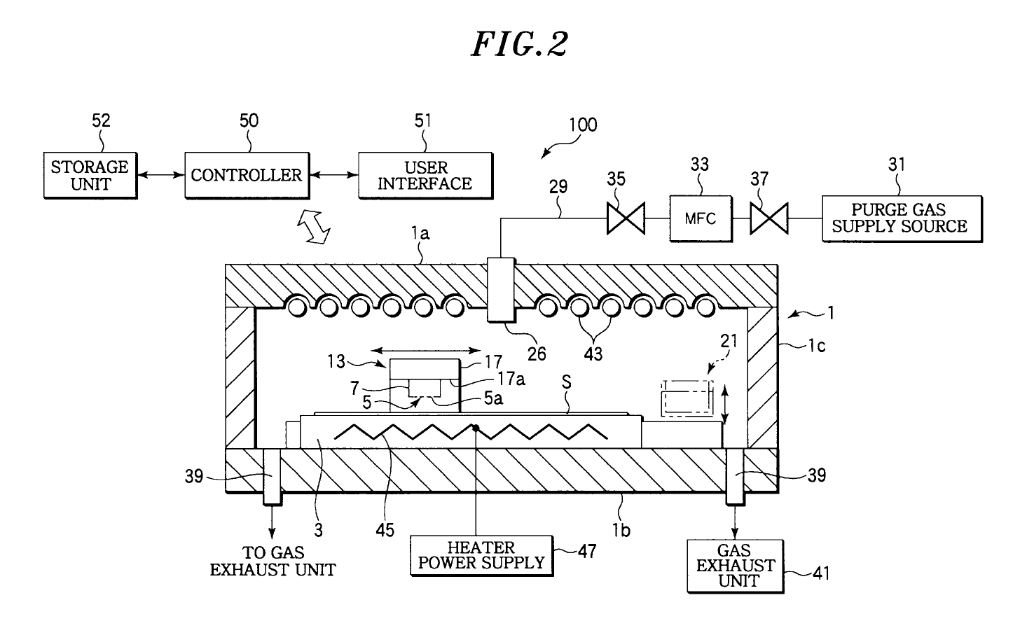

FIG. 1 is a schematic perspective view showing an inner configuration of a semiconductor device manufacturing apparatus in accordance with a first embodiment of the present invention, and FIG. 2 provides a cross sectional view illustrating a schematic configuration of the semiconductor device manufacturing apparatus. A semiconductor device manufacturing apparatus 100 includes a chamber 1 as a first pressure-resistant vessel which accommodates therein, e.g., a substrate S such as a plastic substrate, a glass substrate for use in an FPD (flat panel display) or the like. The chamber 1 is airtightly sealed, and can be depressurized by a gas exhaust unit 41. Further, the substrate S can be loaded and unloaded through a substrate loading/unloading port (not shown). The chamber 1 has therein a stage 3 for horizontally mounting and supporting thereon the loaded substrate S, a carriage 7 having a precision ejection nozzle 5 for ejecting a semiconductor device material in the form of fine liquid droplets toward a top surface (exactly, device forming surface) of the substrate S mounted on the stage 3, and a scanning mechanism 9 for horizontally moving the carriage 7 in a Y direction.

In the scanning mechanism 9, a pair of parallel guide rails 11 extending in the Y direction is provided at both sides of the stage 3. Moreover, a supporting member 13 extends in a X direction to move above the stage 3 and supports the carriage 7 to be horizontally movable in the X direction by driving of an electric motor (not shown) or the like. The supporting member 13 has a pair of leg portions standing on the pair of guide rails 11 to be movable thereon and a guide plate 17 extending over the leg portions 15 to be in parallel with a substrate S mounting surface of the stage 3. The supporting member 13 entirely moves in the Y direction on the guide rails 11 by a driving unit (not shown) having, e.g., an electric motor.

The carriage 7 is attached to the bottom surface of the guide plate 17 via a guide shaft (not shown) to be movable in the X direction. The precision ejection nozzle 5 is provided on the bottom surface (surface facing the stage and the substrate S) of the carriage 7. Further, the precision ejection nozzle 5 can move above the stage 3 along an arbitrary path on the XY plane by the combination of the movement of the supporting member 13 in the Y direction by a driving unit (not shown) and the movement of the carriage 7 in the X direction along the supporting member 13.

The precision ejection nozzle 5 performs ejection of liquid droplets by using a liquid droplet ejection unit corresponding to an inkjet nozzle known in an inkjet printer technical field. The liquid droplet ejection unit in the precision ejection nozzle 5 has, e.g., a plurality of fine nozzle openings 5a and a liquid droplet ejecting head communicating with the corresponding nozzle openings 5a, the liquid droplet ejecting head having a pressure generating chamber (not shown) as a pressure control unit of which inner volume can be increased or decreased by elongation/contraction of a piezoelectric element. Moreover, the volume of the pressure generating chamber is changed by driving the piezoelectric element in accordance with an electric driving signal from a controller 50 (to be described later). Due to the inner pressure increase (pressure control) thus generated at that time, a liquid device material can be ejected through the respective nozzle openings 5a toward the substrate S in the form of fine liquid droplets of several pico-liters to several micro-liters.

Furthermore, the respective nozzle openings 5a of the precision ejection nozzle 5 are connected with liquid material tanks 19a, 19b and 19c mounted in the carriage 7, and various liquid device materials are supplied therefrom. In this embodiment, the liquid material tank 19a accommodates therein a conductive material represented by a conductive polymer, e.g., polyacetylene, polyparaphenylene, polyphenylenevinylene, polypyrrole, poly(3-methylthiophene) or the like; the liquid material tank 19b accommodates therein an insulating material, e.g., polyvinylphenol or the like; and the liquid material tank 19c accommodates therein a semiconductor material, e.g., α,α′-didecylpentathiophene, α,α′-didecylheptathiophene, α,α′-didecylhexathiophene, α,α′-dihexylhexathiophene, α,α′-diethylhexathiophene, hexathiophene or the like. In addition, by arranging a liquid material tank accommodating therein surfactant, e.g., dodecylbenzenesulfonate, ethyleneglycol or the like, the surfactant can be ejected therefrom.

Further, the configuration of the precision ejection nozzle 5 is not limited to the above configuration as long as it enables a semiconductor device material to be ejected in the form of fine liquid droplets.

A sealing member 21 is arranged in a waiting position where the supporting member 13 does not face the stage 3 (and the substrate S). Further, the waiting position where the precision ejection nozzle 5 is on standby may be set at any place inside the chamber 1, or may be positioned outside the chamber 1. The sealing member 21 is a housing having an open top which is formed of a pressure-resistance vessel made of, e.g., metal or the like, and can be raised and lowered by an elevation mechanism (not shown). An edge 21a of the opening thereof is made of a polymer material having elasticity, e.g., elastomer such as rubber, fluorine-based resin, polyimide or the like.

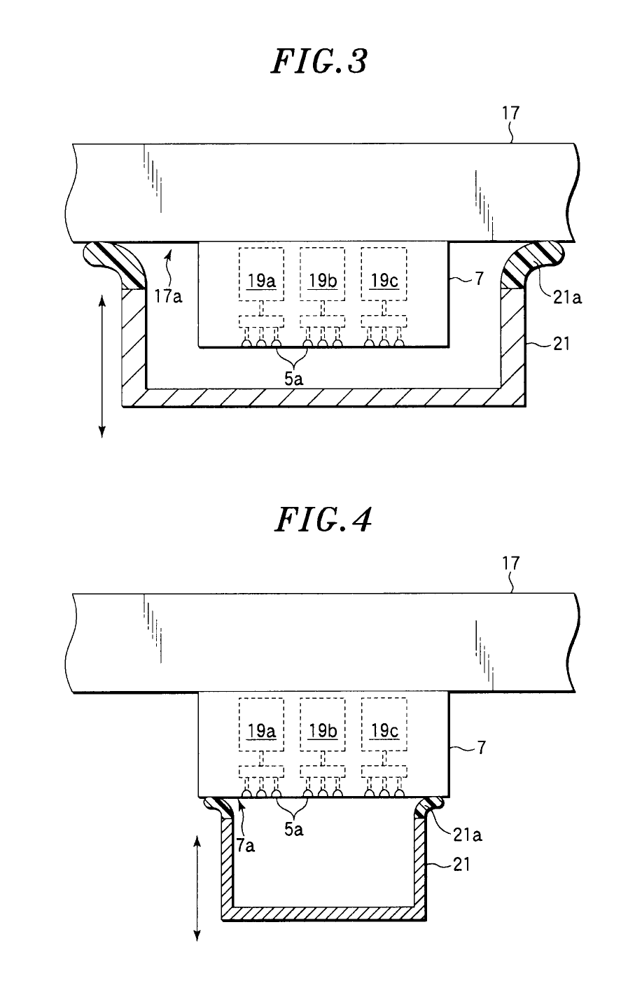

FIGS. 3 to 6 provide enlarged views of isolation structures using the sealing member 21. First, in the example shown in FIG. 3, the edge 21a of the opening of the sealing member 21 is firmly pressed against a bottom surface (contact surface 17a) of the guide plate 17 of the supporting member 13. As such, in order to isolate the precision ejection nozzle 5 in a state where the inside of the chamber 1 is depressurized, the bottom surface of the guide plate 17 of the supporting member 13 serves as the contact surface 17a to be in airtight contact with the sealing member 21 which is a second pressure-resistant vessel.

In this case, the carriage 7 is entirely accommodated inside the sealing member 21, and is isolated from the outside atmosphere. Moreover, the edge 21a of the sealing member 21 is elastically deformed by a pressing force when it is firmly pressed against the contact surface 17a of the guide plate 17, thereby ensuring airtightness. The edge 21a is preferably formed in, e.g., a bellows shape or the like that can be easily pressed when the pressing force is applied, so that the airtightness can be desirably maintained.

FIG. 4 shows another example of the isolation structure using the sealing member 21, and illustrates a state where the sealing member 21 is in contact with a nozzle forming surface 7a of the carriage 7. That is, in this case, the nozzle forming surface 7a of the carriage 7 serves as a contact surface. A plurality of nozzle openings 5a is formed in the nozzle forming surface 7a. When the edge 21a of the opening of the sealing member 21 is firmly pressed against the nozzle forming surface 7a to surround the nozzle openings 5a, the airtightness can be ensured because the edge 21a is elastically deformed by a pressing force. Accordingly, the nozzle openings 5a are isolated and are prevented from being affected due to the change in the outer pressure.

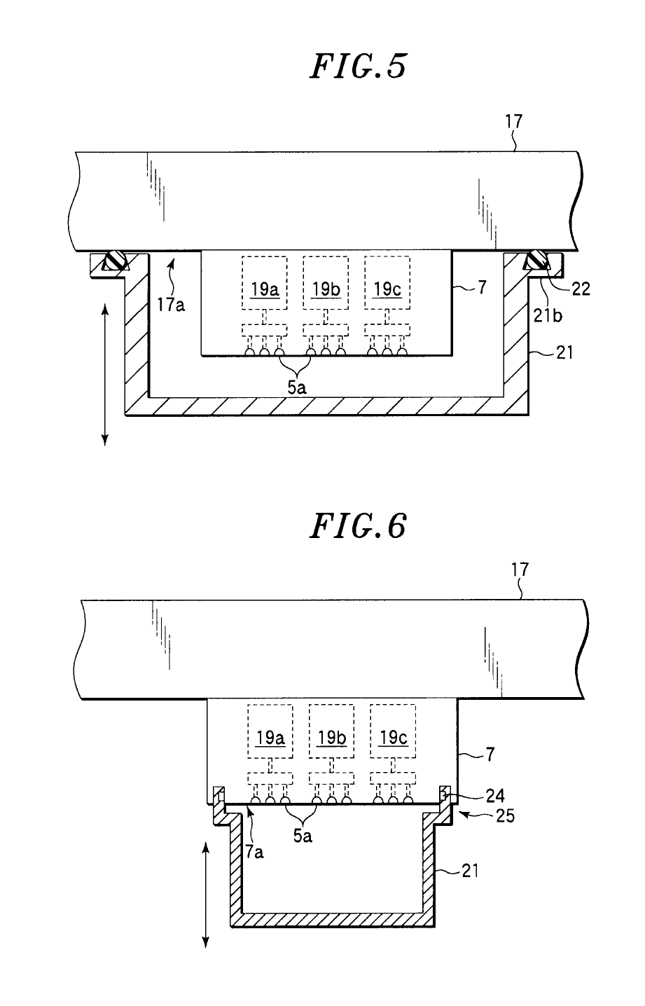

Moreover, in the example shown in FIG. 5, the sealing member 21 has a flange 21b. By pressing the flange 21b against the contact surface 17a of the guide plate 17 via a seal member 22 such as an O ring or the like, it is possible to ensure airtightness and isolate the precision ejection nozzle 5.

Furthermore, the example illustrated in FIG. 6 is configured such that the edge of the sealing member 21 is insertion-fitted to the nozzle forming surface 7a of the carriage 7. By providing a seal member 24 such as an O ring or the like at this insertion-fitting portion 25, the precision ejection nozzle 5 can be isolated. Further, the isolation structure of the precision ejection nozzle 5 using the sealing member 21 is not limited to the examples illustrated in FIGS. 3 to 6, and may vary as long as the airtightness can be ensured.

As described in FIG. 2, a gas introduction section 26 for introducing a gas into the chamber 1 is provided at a central portion of a top plate 1a of the chamber 1, and the gas introduction section 26 is connected with a purge gas supply source 31 for supplying a purge gas, e.g., Ar, N₂ or the like, via a gas supply line 29. Provided in the middle of the gas supply line 29 are a mass flow controller (MFC) and valves 35 and 37 disposed at an upstream and a downstream side thereof. The purge gas can be introduced at a predetermined flow rate into the chamber 1 via the gas introduction section 26.

Moreover, the gas introduction section 26 is not necessarily provided at an upper portion of the chamber 1, and may be provided on a sidewall is or a bottom plate 1b of the chamber 1.

In addition, a plurality of gas exhaust ports 39 is provided on the bottom plate 1b of the chamber 1, and these gas exhaust ports 39 are connected with the gas exhaust unit 41 having a vacuum pump (not shown). Further, by operating the gas exhaust unit 41, the inside of the chamber 1 can be exhausted to a predetermined depressurized state via the gas exhaust ports 39. Besides, in order to effectively replace the atmosphere in the chamber with a purge gas, the gas introduction section 26 and the gas exhaust ports 39 are preferably arranged to opposite to each other as shown in FIG. 2, instead of being arranged side by side.

A plurality of heating lamps 43, e.g., tungsten lamps or the like, is provided on the top plate 1a of the chamber 1 to increase a temperature in the chamber 1. Further, a resistance heater 45 is buried in the stage 3. The stage 3 is heated by supplying power from a heater power supply 47 to the resistance heater 45, so that a substrate S mounted thereon can also be heated. Furthermore, the heating unit (heating tool) such as the heating lamps 43, the resistance heater 45 or the like may be provided either at the upper portion (the top plate 1a) or the lower portion (the stage 3 or the bottom plate 1b) of the chamber 1. However, if heating units are provided at both of the upper and the lower portions as shown in FIG. 2, heating time is shortened and, hence, device manufacturing throughput can be improved.

Each component of the device manufacturing apparatus 100 is connected to and controlled by a controller 50 having a microprocessor (computer). The controller 50 is connected to a user interface 51 including a keyboard for an operator to input a command to operate the device manufacturing apparatus 100, a display for visualizing and displaying an operational status of the device manufacturing apparatus 100 and the like.

Moreover, the controller 50 is connected with a storage unit 52 which stores therein control programs for implementing various processes in the device manufacturing apparatus 100 under the control of the controller 50, and recipes including processing condition data and the like.

Further, if necessary, the controller 50 executes a recipe read from the storage unit 52 in response to instructions from the user interface 51, thereby implementing a required process in the device manufacturing apparatus 100 under the control of the controller 50. The recipes can be stored in a computer-readable storage medium, e.g., a CD-ROM, a DVD, a hard disk, a flexible disk, a flash memory or the like, or transmitted on-line from another apparatus via, e.g., a dedicated line.

With the above configuration, the device manufacturing apparatus 100 can manufacture a semiconductor device, e.g., a transistor or the like, by ejecting a liquid device material toward a preset region on the substrate S.

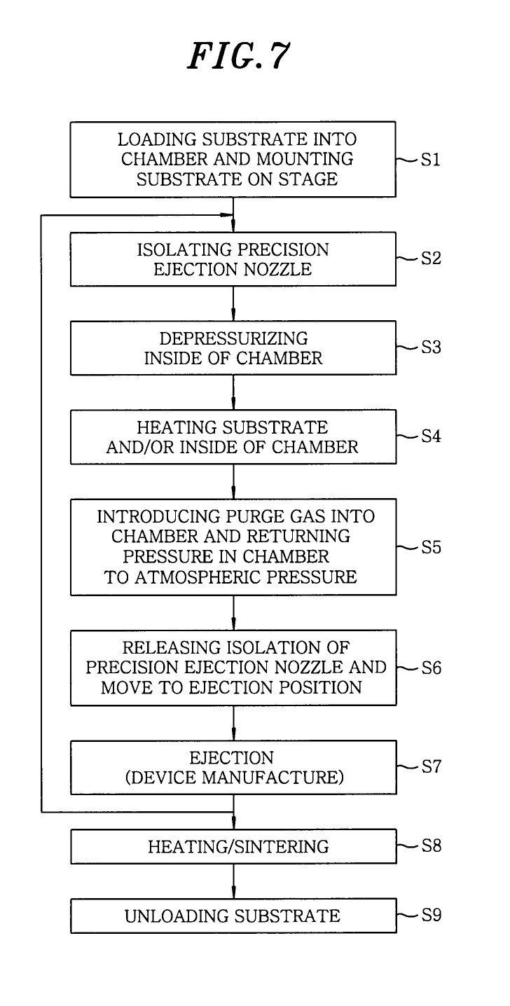

In the device manufacturing apparatus 100 configured as described above, a semiconductor device is manufactured in a sequence shown in, e.g., FIG. 7.

First, a substrate S is loaded into the chamber 1 through a substrate loading/unloading port (not shown), and then is mounted on the stage 3 (step S1).

Next, by sliding the supporting member 13 along the pair of guide rails 11, the carriage 7 moves to a waiting position, i.e., a position where the precision ejection nozzle 5 is away from a position facing the substrate S so as to face the sealing member 21. In that state, the sealing member 21 is lifted to cause the edge 21a of the sealing member 21 to be in contact with the contact surface 17a of the supporting member 13, and the precision ejection nozzle 5 is isolated (step S2).

In the state where the precision ejection nozzle 5 is isolated, the gas exhaust unit 41 is operated to depressurize the inside of the chamber 1 to a predetermined pressure (step S3). Accordingly, moisture and oxygen in the atmosphere in the chamber 1 can be removed, and volatile components of chemical substances, solvents and the like, which are volatilized from a film formed on the substrate S, can also be removed. Even in the depressurized state, since the precision ejection nozzle 5 is isolated by the sealing member 21, a pressure in the nozzle openings 5a of the precision ejection nozzle 5 is maintained at the atmospheric pressure, and the meniscuses can be desirably maintained.

Next, the inside atmosphere of the chamber 1 and the susceptor S are heated to predetermined temperatures by supplying power either to the heating lamps 43 provided at the ceiling portion of the chamber 1 or to the resistance heater 45 buried in the stage 3, or to both of them (step S4). The heating process is optional.

Thereafter, in the state where the precision ejection nozzle 5 is isolated, a purge gas is introduced from the purge gas supply source 31 into the chamber 1 through the gas introduction section 26. Further, the atmosphere in the chamber 1 is replaced with the purge gas and the pressure in the chamber 1 is returned to the atmospheric pressure (step S5).

After the pressure in the chamber 1 is returned to the atmospheric pressure by the introduction of the purge gas, the sealing member 21 is lowered to release the isolation of the precision ejection nozzle 5. Further, by moving the supporting member 13, the precision ejection nozzle 5 of the carriage 7 moves from the waiting position to the ejection position where the precision ejection nozzle 5 faces the substrate S mounted on the stage 3 (step S6). Next, liquid droplets of a liquid device material are ejected toward the surface of the substrate S while the carriage 7 is reciprocated in the X direction (step S7). Each of a conductive liquid material, an insulating liquid material and a semiconductor liquid material is ejected in the form of fine liquid droplets of several pico-liters to several micro-liters from the precision ejection nozzle 5, so that a fine device structure can be formed on the substrate S. Moreover, the replacement of the atmosphere is performed by the introduction of the purge gas after the ejection space where the fine liquid droplets travel toward the substrate S is depressurized by exhaustion. Hence, the components of the liquid material do not deteriorate, which makes it possible to manufacture a high-quality device.

When a semiconductor device is manufactured by using the device manufacturing apparatus 100, each of the aforementioned steps S2 to S7 may be performed a single time. However, depending on types of semiconductor devices to be manufactured, the steps S2 to S7 may be repeated by returning to the step S2 after completion of the step S7, as can be seen from FIG. 7.

Upon completion of the ejection, the device formed on the substrate S is heated and sintered at a temperature of about 50° C. to about 100° C. by supplying power either to the heating lamps 43 provided at the ceiling portion of the chamber 1 or to the resistance heater 45 buried in the stage 3, or to both of them if necessary (step S8). Accordingly, the components such as solvents and the like contained in the liquid material are volatilized and removed, thereby hardening the device. The heating/sintering process of the step S8 is optional.

In a conventional inkjet coating method, the ejection space, where the liquid droplets ejected from the nozzle arrive at the surface of the object to be processed, needs to be maintained under the atmospheric pressure condition. However, in the present embodiment, the precision ejection nozzle 5 can be isolated by the sealing member 21, and inside of the chamber 1 can be switched between the atmospheric state and the vacuum state. As a consequence, the leakage of the liquid droplets from the nozzle opening 5a can be prevented, and a device can be produced by the coating method even after the vacuum state.

Thereafter, the substrate S mounted on the stage 3 is unloaded to the outside of the chamber 1 through the substrate loading/unloading port (not shown) (step S9). By performing a series of the steps S1 to S9, the manufacturing of devices for a single substrate S is completed.

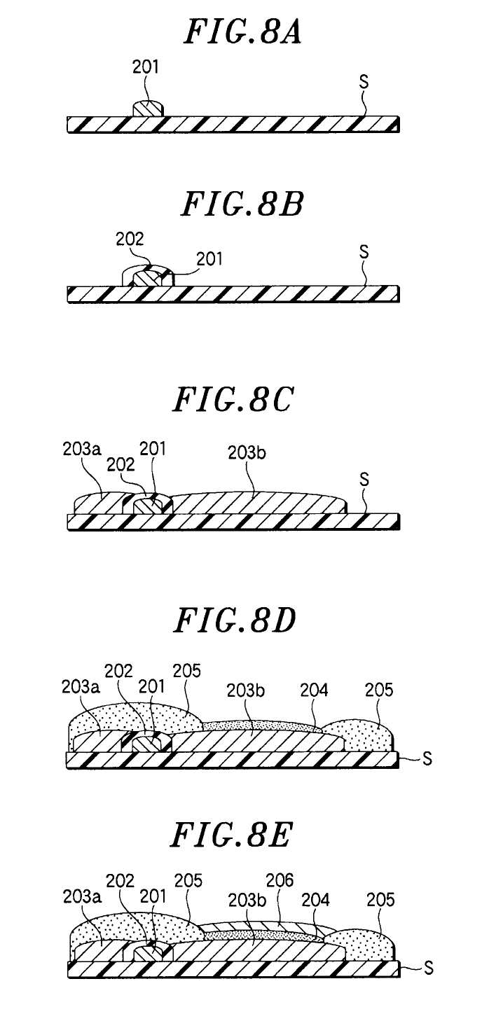

Hereinafter, a schematic manufacturing process for manufacturing a memory cell which can be used in a DRAM (Dynamic Random Access Memory) or the like by using the device manufacturing apparatus 100 will be described. FIGS. 8A to 8E are cross sectional views showing processes for manufacturing a memory cell which can be used in a DRAM by using the device manufacturing apparatus 100. First, as illustrated in FIG. 8A, a conductive material is ejected from the liquid material tank 19a mounted in the carriage 7 toward a surface of the substrate S made of, e.g., PET (polyethyleneterephthalate), through the precision ejection nozzle 5, thereby forming a gate electrode 201.

Thereafter, as depicted in FIG. 8B, an insulating material is ejected from the liquid material tank 19b, so that a laminated film 202 (including a laminated structure of a gate insulating film and a semiconductor film; only the insulating film is shown) is formed so as to cover the gate electrode 201. Next, a conductive material is ejected from the liquid material tank 19a toward a region adjacent to a gate structure thus formed through the precision ejection nozzle 5, thereby forming source/drain electrodes 203a and 203b, as can be seen from FIG. 8C. Then, an insulating material is ejected from the liquid material tank 19b, so that a dielectric film 204 and an insulating film 205 are formed to cover the source/drain electrodes 203a and 203b, as described in FIG. 8D. Thereafter, a conductive material is ejected from the liquid material tank 19a through the precision ejection nozzle 5, thus forming a capacitor electrode 206 to cover the dielectric film 204, as illustrated in FIG. 8E.

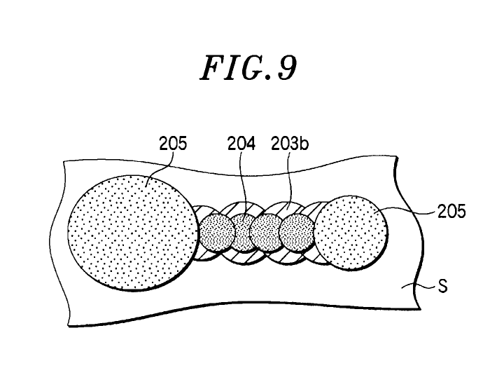

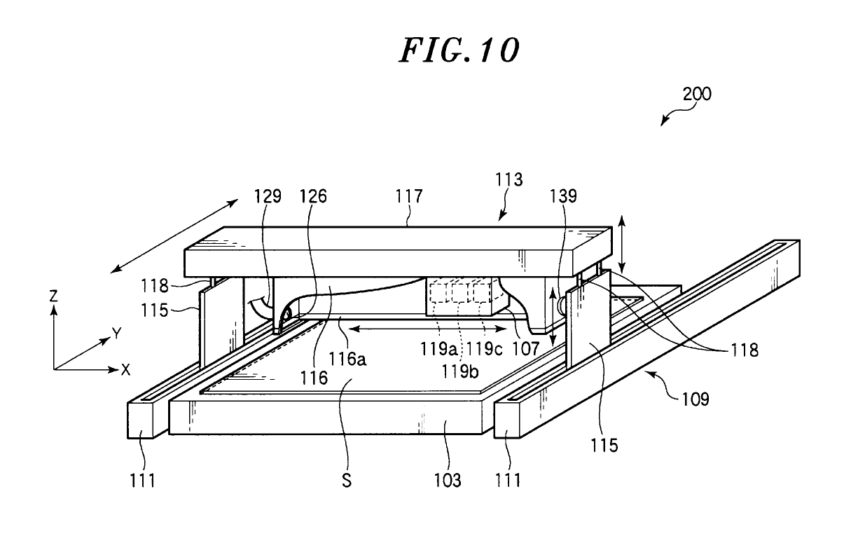

FIG. 9 is a top view of the step of FIG. 8D (the state where the dielectric film 204 is formed). The liquid droplets of the device material ejected from the precision ejection nozzle 5 spread in a circular shape on the surface of the substrate S and overlap with other liquid device materials while the liquid droplets are sequentially ejected. Thus, a semiconductor device of a desired structure can be formed on the surface of the substrate S without requiring a photolithography process or an etching process and equipments therefor.

### Second Embodiment

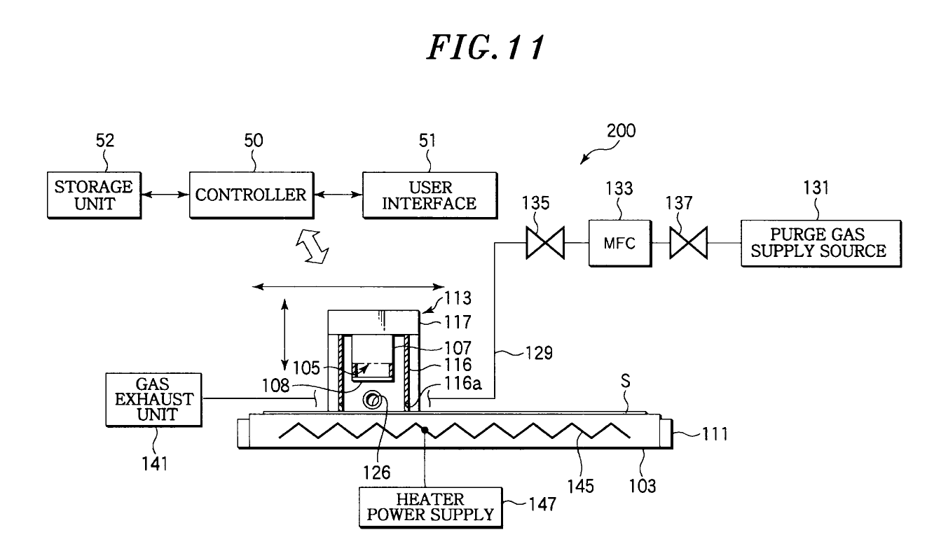

FIG. 10 is a perspective view showing a schematic configuration of a semiconductor device manufacturing apparatus 200 in accordance with a second embodiment of the present invention, and FIG. 11 illustrates a schematic side view thereof. The semiconductor device manufacturing apparatus 200 of this embodiment has the configuration which does not require a chamber, and therefore can be effectively used in the case where a substrate S cannot accommodated in a chamber due to a large size thereof.

The semiconductor device manufacturing apparatus 200 includes a stage 103 for horizontally mounting and supporting thereon a substrate S, e.g., a plastic substrate, a glass substrate for use in an FPD or the like, a carriage 107 having a precision ejection nozzle 105 for ejecting a semiconductor device material in the form of fine liquid droplets toward a top surface (exactly, device forming surface) of a substrate S mounted on the stage 103, and a scanning mechanism 109 for horizontally moving the carriage 107 in a Y direction.

In the scanning mechanism 109, a pair of parallel guide rails 111 extending in the Y direction is provided at both sides of the stage 103. Further, a supporting member 113 extends in the X direction to move above the stage 103 and supports the carriage 107 to be horizontally movable in the X direction by driving of an electric motor (not shown) or the like. The supporting member 113 has a pair of leg portions 115 standing on the pair of guide rails 111 so as to be movable thereon and a guide plate 117 extending over the leg portions 115 so as to be in parallel with a substrate S mounting surface of the stage 103. The supporting member 113 entirely moves in the Y direction on the guide rails 111 by a driving unit (not shown) having, e.g., an electric motor.

Moreover, an elevation mechanism (not illustrated) is provided at the guide plate 117 so as to be raised and lowered in a vertical direction with respect to the leg portions 115 via elevating shafts 118.

The carriage 107 is attached to the bottom surface of the guide plate 117 via a guide shaft (not shown) so as to be movable in the X direction. The precision ejection nozzle 105 is provided on the bottom surface (surface facing the stage 103 and the substrate S) of the carriage 107. Further, the precision ejection nozzle 105 can move above the stage 103 along an arbitrary path on the XY plane by the combination of the movement of the supporting member 113 in the Y direction by a driving unit (not shown) and the movement of the carriage 107 in the X direction along the supporting member 113.

Since the precision ejection nozzle 105 has the configuration same as that of the precision ejection nozzle 5 of the first embodiment, the description thereof will be omitted. Further, the precision ejection nozzle 105 is connected with liquid material tanks 119a, 119b and 119c mounted in the carriage 107, and various liquid materials are supplied therefrom. The liquid material tank 119a has therein a conductive material; the liquid material tank 119b has therein an insulating material; and the liquid material tank 119c has therein a semiconductor material.

In addition, a frame 116 serving as a pressure-resistant vessel that can be in contact with or separated from the surface of the object to be processed is provided on the bottom surface of the guide plate 117 of the supporting member 113 to surround the periphery of the carriage 107. Further, FIG. 10 is a partially cutout view of the frame 116. The frame 116 has an upper portion substantially perpendicularly connected to the bottom surface of the guide plate 117 and an open lower portion. An edge 116a of the opening is made of, e.g., elastomer such as rubber or the like as a sealing member. By vertically moving the guide plate 117, the edge 116a of the frame 116 can be in contact with or separated from the surface of the substrate S.

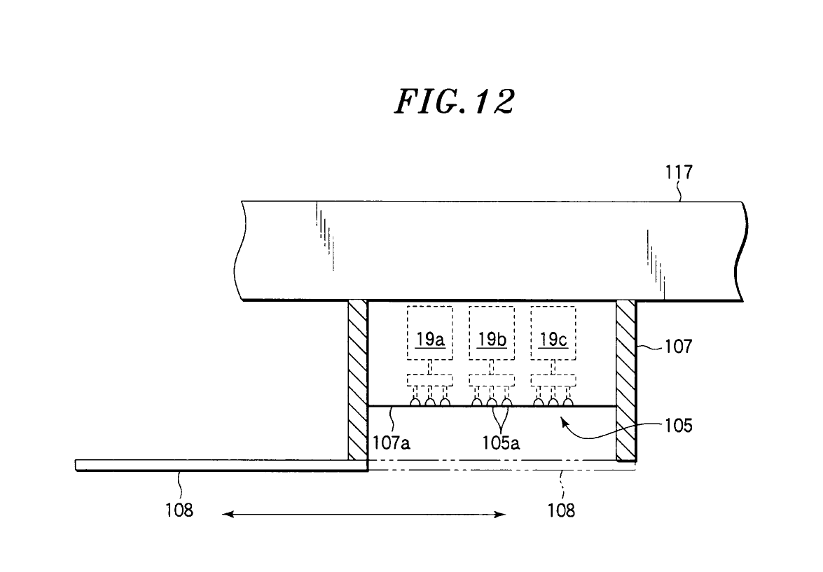

A partition plate 108 capable of sliding in a horizontal direction is provided below the carriage 107 disposed inside of the frame 116 to be surrounded. As illustrated in FIG. 12, the partition plate 108 slides in parallel with the nozzle forming surface 107a by a driving unit such as an electric motor (not shown) or the like. When the partition plate 108 is closed, the nozzle openings 105a are isolated from the outside atmosphere, and when the partition plate 108 is opened, the nozzle openings 105a open to the outside atmosphere. Therefore, when the pressure inside the frame 116 is depressurized, the nozzle openings 105a can be sealed so as not to be exposed to the ejection space.

A gas introduction section 126 is provided at a side portion of the frame 116, and the gas introduction section 126 is connected to a purge gas supply source 131 for supplying a purge gas, e.g., Ar, N₂ or the like, via a gas supply line 129. Provided in the middle of the gas supply line 129 are a mass flow controller 133, and valves 135 and 137 disposed at an upstream and a downstream side thereof. The purge gas can be introduced at a predetermined flow rate into the frame 116 via the gas introduction section 126.

Besides, a gas exhaust port 139 is provided at a side portion of the frame 116 opposite to the gas introduction section 126, and the gas exhaust port 139 is connected to a gas exhaust unit 141 having a vacuum pump (not shown). Further, by operating the gas exhaust unit 141 while the frame 116 is being in contact with the substrate S, the inside of the frame 116 can be exhausted to a predetermined depressurized state through the gas exhaust port 139.

The resistance heater 145 is buried in the stage 103. The stage 103 can be heated by supplying power from a heater power supply 147 to the resistance heater 145, so that the substrate S mounted thereon can also be heated.

In the semiconductor device manufacturing apparatus 200 configured as described above, a semiconductor device, e.g., a transistor or the like can be formed by ejecting a liquid device material to a preset region on the substrate S.

Further, the other parts of the semiconductor device manufacturing apparatus 200 are the same as those of the device manufacturing apparatus 100 of the first embodiment. Therefore, like reference numerals will be used for like parts, and the description thereof will be omitted.

In the semiconductor device manufacturing apparatus 200 configured as described above, a semiconductor device is produced in a sequence shown in, e.g., FIG. 14.

First, the substrate S is mounted on the stage 103, and the supporting member 113 slides along the guide rails 111 until the frame 116 is positioned above the substrate S (step S11). In this state, the partition plate 108 is closed to isolate the nozzle openings 105a of the precision ejection nozzle 105 from the outside atmosphere.

Next, the frame 116 is lowered to cause the edge 116a of the frame 116 to be in contact with the top surface of the substrate S (device forming surface) (step S12). Then, the inside of the frame 116 is exhausted to a depressurized state by operating the gas exhaust unit 141 (step S13). Accordingly, moisture and oxygen in the ejection space inside the frame 116 can be removed, and volatile components of chemical substances, solvents and the like, which are volatilized from a film formed on the substrate S can also be removed. Even in the depressurized state, since the precision ejection nozzle 105 is isolated by the partition member 108, a pressure in the nozzle openings 105a of the precision ejection nozzle 105 is maintained at the atmospheric pressure and the meniscuses can be desirably maintained.

Next, the substrate S is heated to a predetermined temperature by supplying power to the resistance heater 145 buried in the stage 103 (step S14). The heating process is optional.

Thereafter, in the state where the precision ejection nozzle 105 is isolated, the purge gas is introduced from the purge gas supply source 131 into the frame 116 through the gas introduction section 126. Further, the atmosphere in the frame 116 is replaced with the purge gas and the pressure in the frame 116 is returned to the atmospheric pressure (step S15).

After the inside of the frame 116 is returned to the atmospheric pressure by the introduction of the purge gas, the isolation of the precision ejection nozzle 105 is released by sliding the partition plate 108 to the open position (step S16). Then, the liquid droplets of the semiconductor device material are ejected toward the surface of the substrate S while the carriage 107 is reciprocated in the X direction (step S17). Each of a conductive liquid material, an insulating liquid material and a semiconductor liquid material in the form of fine liquid droplets of several pico-liters to several micro-liters is ejected from the precision ejection nozzle 105, so that a fine device structure can be formed on the substrate S. Moreover, the replacement of the atmosphere is performed by the introduction of the purge gas after the ejection space where the fine liquid droplets travel toward the substrate S is depressurized by exhaustion. Hence, the components of the liquid material do not deteriorate, and adverse effects to the device can be prevented.

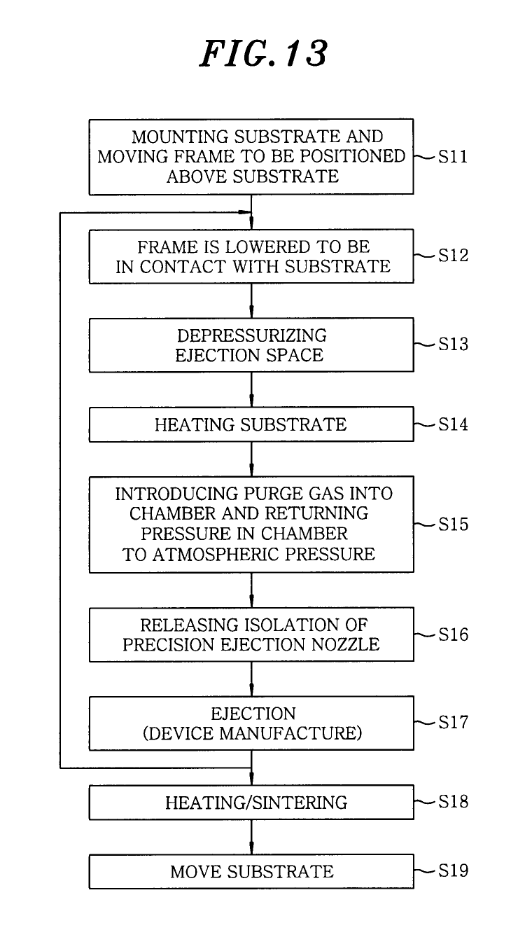

When a semiconductor device is manufactured by using the semiconductor device manufacturing apparatus 200, each of the aforementioned steps S12 to S17 may be performed a single time. However, depending on types of semiconductor devices to be manufactured, the steps S12 to S17 may be repeated, as can be seen from FIG. 13.

Upon completion of the ejection, the device formed on the substrate S is heated and sintered at a temperature of about 50° C. to about 100° C. by supplying, when necessary, power to the resistance heater 145 buried in the stage 103 (step S18). Accordingly, the components such as solvents and the like contained in the liquid material can be volatilized and removed. The heating/sintering process of the step S18 is optional.

Next, the substrate S mounted on the stage 103 is moved by a transfer mechanism (not shown) (step S19). By performing a series of the steps S11 to S19, the manufacture of devices for a single substrate S is completed. As a consequence, semiconductor devices such as a transistor, a capacitor and the like can be produced on the surface of the substrate S without requiring a photolithography process, an etching process and equipments therefor.

In the present embodiment as well as in the first embodiment, inside of the frame 116 can be switched between the atmospheric state and the vacuum state. Accordingly, the leakage of the liquid droplets from the nozzle openings 105a can be prevented, and a device can be produced by the coating method even after the vacuum state.

Although the present invention has been described in detail with reference to the above-described embodiments, the present invention may be variously modified without being limited to the above-described embodiments. For example, in the above description, a rectangular large substrate such as a glass substrate for use in an FPD or the like is used as a substrate S. However, the present can also be applied to the case where a semiconductor substrate such as silicon wafer or the like is used as an object to be processed.

### INDUSTRIAL APPLICABILITY

The present invention can be preferably used for manufacture of various semiconductor devices, e.g., a transistor, a capacitor, a TFT device and the like.

What is claimed is:

1. A semiconductor device manufacturing method for producing a semiconductor device on a surface of an object to be processed by using a semiconductor device manufacturing apparatus including: a first vessel having a mounting table for mounting thereon the object to be processed; a gas supply unit that supplies a purge gas into the first vessel; a gas exhaust unit that depressurizes the inside of the first vessel; a liquid droplet ejection unit that ejects a semiconductor device material in the form of liquid droplets from liquid droplet ejection nozzles disposed to face the mounting table toward the object to be processed; a moving unit that moves the liquid droplet ejection nozzles between an ejection position where the liquid droplets are ejected toward the object to be processed and a waiting position where the liquid droplets are not ejected; and a second vessel that isolates the liquid droplet ejection nozzles in the waiting position and that maintains the liquid droplet ejection nozzles in an atmospheric pressure state while the inside of the first vessel is in depressurized state, the semiconductor device manufacturing method comprising:
loading the object to be processed into the first vessel to be mounted on the mounting table;
depressurizing the inside of the first vessel in a state where the liquid droplet ejection nozzle is isolated by the second vessel in the waiting position;
introducing the purge gas from the gas supply unit into the first vessel to replace the atmosphere in the first vessel with the purge gas and return a pressure in the first vessel to an atmospheric pressure; and
releasing the isolation of the liquid droplet ejection nozzles, which is caused by the second vessel and moving the liquid droplet ejection nozzles to the ejection position to eject the liquid droplets toward the object to be processed.

2. The semiconductor device manufacturing method of claim 1, further comprising: heating the mounting table and the first vessel before the replacement of the atmosphere.

3. The semiconductor device manufacturing method of claim 1, further comprising: sintering the formed device after the ejection of the liquid droplets from the liquid droplet ejection nozzle.

4. A semiconductor device manufacturing method for producing a semiconductor device on a surface of an object to be processed by using a semiconductor device manufacturing apparatus including: a mounting table for mounting thereon the object to be processed; a liquid droplet ejection unit that ejects a semiconductor device material in the form of liquid droplets from a liquid droplet ejection nozzle disposed to face the mounting table toward the object to be processed; a vessel having an opening, said vessel being movable, by a controller, from a first position where the opening is in contact with a surface of the object to be processed and a second position where the opening is separated from the surface of the object to be processed, the vessel defining an ejection space where the liquid droplets ejected from the liquid droplet ejection nozzle travel, and the liquid droplet ejection unit being accommodated in the vessel; a nozzle isolation unit that isolates the liquid droplet ejection nozzle from the ejection space while an inside of the vessel is in a depressurized state; a gas supply unit that supplies a purge gas into the corresponding vessel in a state where the vessel is in contact with the surface of the object to be processed; a gas exhaust unit that depressurizes the inside of the vessel in a state where the vessel is in contact with the surface of the object to be processed; and a moving unit that moves the liquid droplet ejection unit relative to the mounting table, the semiconductor device manufacturing method comprising:
moving the vessel relative to the object to be processed so as to face each other;
causing the opening of the vessel to be in contact with the surface of the object to be processed;
depressurizing the inside of the ejection space in a state where the liquid droplet ejection nozzle is isolated by the isolation unit inside the vessel;
introducing the purge gas from the gas supply unit into the first vessel to replace the atmosphere in the first vessel with the purge gas and return a pressure in the first vessel to an atmospheric pressure;
releasing the isolation of the liquid droplet ejection nozzle by the isolation unit; and
ejecting the liquid droplets from the liquid droplet ejection nozzle toward the object to be processed.

5. The semiconductor device manufacturing method of claim 4, further comprising: heating the mounting table before the replacement of the atmosphere.

6. The semiconductor device manufacturing method of claim 4, further comprising: sintering the formed device after the ejection of the liquid droplets from the liquid droplet ejection nozzle.
